(19) United States
(12) Patent Application Publication
(10) Pub. No.: US 2025/0324643 A1
(43) Pub. Date: Oct. 16, 2025

(54) GAN HEMT EPITAXIAL WAFER BASED ON ALN THICK FILM AND MANUFACTURING METHOD OF THE SAME

(71) Applicant: WAVELORD CO., LTD., Gyeonggi-do (KR)

(72) Inventors: June O SONG, Gyeonggi-do (KR); Hyun Chul Lim, Gyeonggi-do (KR); Young Hun Han, Gyeonggi-do (KR); Hyung Sun Yun, Gyeonggi-do (KR)

(21) Appl. No.: 19/176,432

(22) Filed: Apr. 11, 2025

(30) Foreign Application Priority Data
Apr. 12, 2024 (KR) 10-2024-0049549
Feb. 17, 2025 (KR) 10-2025-0020431

(51) Int. Cl. H10D 30/47; H01L 21/02; H01L 21/322; H10D 62/40; H10D 62/824

(52) U.S. Cl. CPC H10D 30/475; H01L 21/02378; H01L 21/02433; H01L 21/02458; H01L 21/0254; H01L 21/0262; H01L 21/3228; H10D 62/405; H10D 62/824

(57) ABSTRACT

Embodiments according to the present invention are an AlN thick film-based GaN HEMT epitaxy wafer comprises a growth substrate made of a semi-insulating material or a conductive material, an AlN nucleation region grown on the growth substrate, an AlN stress control region grown on the AlN nucleation region and having an air void or an Al vacancy, an AlN buffer region grown on the AlN stress control region and not including the air void and the Al vacancy, and an active region grown on the AlN buffer region and including a GaN channel region and an AlGaN barrier region.

### CROSS-REFERENCE TO RELATED APPLICATIONS

This application claims priority to Korean Patent Application Nos. 10-2024-0049549, filed on Apr. 12, 2024 and 10-2025-0020431, filed on Feb. 17, 2025. The entire disclosure of the applications identified in this paragraph is incorporated herein by reference.

### FIELD

The present invention relates to a GaN HEMT power semiconductor epitaxy wafer and a manufacturing method thereof, and is characterized in that it has excellent physical properties of both electrical insulation and heat dissipation by utilizing an AlN thick film having a specific structure.

### BACKGROUND

The GaN HEMT power semiconductor epitaxy structure typically has a structure in which a nucleation region, a stress-relieving region, a buffer region, a channel region, and a barrier region are sequentially stacked on a growth substrate.

In GaN HEMT power semiconductor epitaxy structures, the channel and barrier regions are the key active regions, separate from the substructure.

In the active region, a 2DEG (2-dimensional electron gas) high electron density is formed due to the polarization phenomenon of the group III nitride semiconductor at the channel region interface, which is called a horizontal channel structure.

GaN HEMT power semiconductor epitaxy wafers with a horizontal channel structure have performance and quality degradation issues due to vertical leakage current in the direction of the substructure of the active region, and to solve this, an active region substructure with further enhanced electrical insulation is required.

In addition, in order to quickly and easily release a large amount of heat generated when operating a GaN HEMT power semiconductor device to the outside, it is required to configure the substructure of the active region with a material with high thermal conductivity.

The buffer region has a current blocking function that reduces vertical leakage current by imparting high-resistive properties, and is typically made of GaN material doped with carbon (C) or iron (Fe) as a dopant (C-doped or Fe-doped GaN) to achieve the intended purpose.

However, when growing C- or Fe-doped GaN, the quality of GaN crystals deteriorates. Therefore, developing optimal growth conditions between the growth substrate and the active region is a challenge in the related technical field.

### SUMMARY

### Technical Problem

The present invention provides a structure and method for solving a problem of performance and quality degradation caused by vertical leakage current due to surface damage of a growth substrate during the epitaxy growth process of a GaN HEMT power semiconductor epitaxy wafer having a horizontal channel structure.

The present invention provides a substructure of an active region with enhanced electrical insulation and a method for manufacturing the same, so that not only a growth substrate of a semi-insulating material (SiC, Si) but also a low-cost conductive growth substrate can be used.

The present invention provides a substructure of an active region of a material having high thermal conductivity capable of quickly and easily dissipating a large amount of heat generated during operation of a GaN HEMT power semiconductor device, and a method for manufacturing the same.

### Technical Solution

Embodiments according to the present invention are an AlN thick film-based GaN HEMT epitaxy wafer, comprising: a growth substrate made of a semi-insulating material or a conductive material; an AlN nucleation region grown on the growth substrate; an AlN stress control region grown on the AlN nucleation region and having an air void or an Al vacancy; an AlN buffer region grown on the AlN stress control region and not including the air void and the Al vacancy; and an active region grown on the AlN buffer region and including a GaN channel region and an AlGaN barrier region.

In embodiments according to the present invention, the growth substrate is made of Si having the (111) plane as a growth plane or 4H-SiC having the Si-polar face as a growth plane.

In embodiments according to the present invention, the AlN stress control region is formed to be relatively thicker than the AlN buffer region, and the AlN stress control region is provided with a large amount of micro-level-sized air voids or nano-level-sized Al vacancies.

Embodiments according to the present invention further comprise a back barrier region made of Al(1-z)Ga(z)N (0<z<1), which is grown prior to the growth of the active region on the AlN buffer region.

Embodiments according to the present invention are methods for manufacturing a GaN HEMT epitaxy wafer based on an AlN thick film, wherein the step of forming an AlN stress control region having a large amount of air voids comprises a carrier gas that moves an aluminum organic metal source (TMAl, TEAl) into a MOCVD chamber, which is made of N₂ alone or a gas mixed with a small amount of H₂ (i.e., an N₂-rich atmosphere).

Here, the step of forming the AlN stress control region may include a step of forming an AlN surface patterning through lithography and etching after growing the AlN nucleation region by a MOCVD process or after growing a portion of the AlN stress control region to a predetermined thickness; and a step of completing the AlN stress control region through regrowth on the AlN surface patterning in MOCVD.

The step of forming the AlN stress control region may include a step of growing AlGaN or AlInN material at a predetermined temperature (Tg) as a subsequent process after growing the AlN nucleation region, and decomposing and evaporating Ga or In at a high temperature higher than Tg and in a H₂ reduction atmosphere.

The step of forming the AlN stress control region can be formed to a set thickness by using a 2-dimensional growth mode in which AlN is preferentially grown in the horizontal direction through a pulsed NHs source supply, and a 3-dimensional growth mode in which AlN is preferentially grown in the vertical direction through a continuous NH₃ source supply.

The step of forming the AlN stress control region is preferably performed by controlling the V (N source)/III (Al source) ratio below a predetermined growth pressure in MOCVD and supplying a Ga source and an In source for isoelectric co-doping during AlN growth. As a result, a large amount of Al vacancies are generated.

The step of forming the AlN buffer region can be formed in a 2D growth mode using a carrier gas, H₂ alone or a gas mixed with a small amount of N₂ (i.e., H₂-rich atmosphere), for moving an aluminum organic metal source (TMAl, TEAl) into the MOCVD chamber.

Here, the 2D growth mode functions to eliminate and minimize the density of threading dislocations and crystal defects caused in the AlN nucleation region.

### Advantageous Effects

According to the present invention, by introducing an AlN stress control region and an AlN buffer region defined as an ‘AlN thick film’, a substructure having excellent electrical insulation for an active region can be formed not only on a semi-insulating growth substrate but also on a relatively inexpensive conductive growth substrate.

According to the present invention, the ‘AlN thick film’ prevents vertical leakage current caused by surface damage of a growth substrate during the growth process. This prevents performance and quality deterioration.

According to the present invention, since the ‘AlN thick film’ has sufficient thermal conductivity, a large amount of heat generated when operating a GaN HEMT power semiconductor device can be quickly and easily released.

According to the present invention, by forming a back barrier region made of Al(1-z)Ga(z)N (0<z<1) on an AlN buffer region, the effect of confining 2DEG carrier electrons in the channel region can be maximized.

In addition, the back barrier region minimizes crystal defects by alleviating the lattice constant difference between the AlN buffer region and the GaN channel region, and at the same time, induces compressive stress that compensates for tensile stress to eliminate microcracks.

According to the present invention, since the ‘AlN thick film’ is composed of a single material, the growth process time can be shortened, so that a GaN HEMT device can be manufactured at a high cost-effectiveness.

### BRIEF DESCRIPTION OF DRAWINGS

FIG. 1 is a cross-section of a GaN HEMT power semiconductor epitaxy wafer according to one embodiment of the present invention.

FIG. 2 is a cross-section of a GaN HEMT power semiconductor epitaxy wafer according to another embodiment of the present invention.

FIG. 3 is a drawing for explaining a method for manufacturing a GaN HEMT power semiconductor epitaxy wafer according to one embodiment of the present invention.

### DETAILED DESCRIPTION

Hereinafter, embodiments of GaN HEMT epitaxial wafer based on AlN thick film and manufacturing method of the same according to the present invention will be described in detail with reference to the drawings.

The terms used below have been selected for convenience of explanation, and should be appropriately interpreted in a meaning that is consistent with the technical idea of the present invention without being limited to the dictionary meaning.

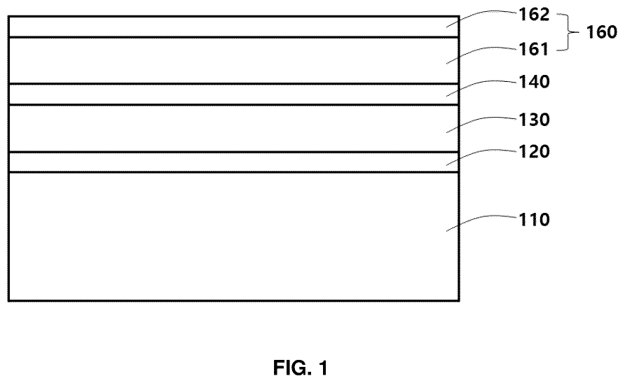

Referring to FIG. 1, in a GaN HEMT power semiconductor epitaxy wafer according to one embodiment of the present invention, an AlN nucleation region (120), an AlN stress control region (130), and an AlN buffer region (140) are sequentially stacked and grown on a growth substrate (110), and a channel region (161) and a barrier region (162) are formed thereon as an active region (160).

The growth substrate (110) is provided with a semi-insulating material or a conductive material.

The growth substrate (110) may be a silicon (Si) substrate, a silicon carbide (SiC) substrate, or an aluminum oxide substrate. The aluminum oxide substrate may be a sapphire (Al₂O₃) substrate.

It is preferable that the silicon (Si) substrate have a (111) plane, which has a high atomic filling rate like a group III nitride crystal structure (HCP, Hexagonal Close-Packed), as a growth plane, rather than the (100) and (110) planes.

The silicon carbide (SiC) substrate is preferably a 4H-SiC substrate, which has the same crystal structure as the group III nitride crystal structure (HCP) and has the smallest lattice constant difference, and it is preferable that it be grown on the Si polar face.

The AlN nucleation region (120) is grown on the growth substrate (110).

The AlN nucleation region (120) is a region that promotes high-quality growth of the ‘AlN thick film’ and the active region (160). In addition, in the case of the Si growth substrate, the AlN nucleation region (120) suppresses the Melt Back Etching phenomenon due to the Si-Ga process reaction.

The AlN nucleation region (120) is a part of the AlN stress control region (130) and can be grown under the same growth conditions as the AlN stress control region (130).

This embodiment is characterized by having an AlN stress control region (130) and an AlN buffer region (140) defined as an ‘AlN thick film’ as the substructure of the active region (160).

The AlN stress control region (130) is provided with AlN, which has a 6.2 eV energy band gap and high resistivity.

The AlN stress control region (130) contains a large amount of micro-level-sized air voids and/or nano-level-sized Al vacancies for stress control.

The AlN buffer region (140) is provided to solve the quality and reliability degradation phenomenon that occurs in the process of doping carbon (C) or iron (Fe) ions to grow conventional high-resistivity GaN materials, and is provided with AlN and does not include air voids or Al vacancies.

Here, the AlN stress control region (130) and the AlN buffer region (140) have a difference in thickness.

The AlN stress control region (130) is provided relatively thickly, and is preferably provided with a thickness of 0.2 to 3 μm.

The AlN buffer region (140) is provided with a relatively thin thickness, and is preferably provided with a thickness of 0.01 to 1 μm.

The AlN stress control region (130) and the AlN buffer region (140), defined as the ‘AlN thick film’, prevent the crystal quality damage of the active region (160) and the resulting leakage current.

In addition, since it has high electrical insulation, in addition to expensive semi-insulating materials, inexpensive electrically conductive materials can be used as a growth substrate.

In addition, it allows a large amount of heat generated when driving a GaN HEMT power semiconductor device to be quickly and easily released.

The active region (160) is grown on the AlN buffer region (140) and includes a GaN channel region (161) and an AlGaN barrier region (162).

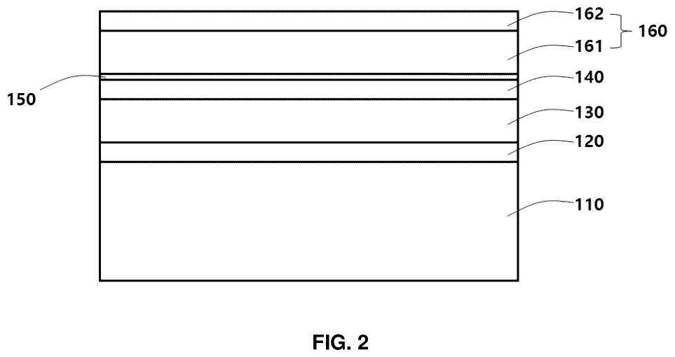

Referring to FIG. 2, another embodiment of the present invention adds a back barrier region (150) to the embodiment of FIG. 1.

The back barrier region (150) is grown before the growth of the active region (160) on the AlN buffer region (140) and is formed of Al(1-z)Ga(z)N (0<z<1) containing gallium (Ga).

In addition, the back barrier region (150) may be formed of a multi-layer structure or a superlattice structure each composed of AlN, AlGaN, and GaN materials.

The back barrier region (150) has a function of maximizing the effect of confining carrier electrons in the 2DEG generated in the channel region of the barrier/channel interface.

In addition, the back barrier region (150) has the function of minimizing crystal defects by alleviating the lattice constant difference between the materials of the AlN buffer region (140) and the GaN channel region (161), and eliminating microcracks by inducing compressive stress that compensates for tensile stress.

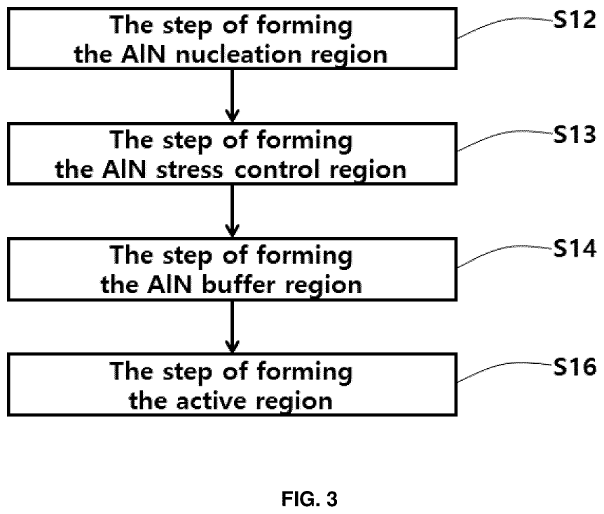

Next, referring to FIG. 3, a method for manufacturing a GaN HEMT epitaxy wafer based on an AlN thick film according to the present invention comprises an AlN nucleation region growth step (S12), an AlN stress control region growth step (S13), an AlN buffer region growth step (S14), and an active region growth step (S16) on a prepared growth substrate (110).

The AlN stress control region (130) contains a large amount of micro-level-sized air voids and/or nano-level-sized Al vacancies for stress control.

The AlN stress control region having a large amount of air voids can be grown using a carrier gas that moves an aluminum organic metal source (TMAl, TEAl) into the MOCVD chamber as N₂ alone or a gas mixed with a small amount of H₂ (i.e., N₂-rich atmosphere).

H₂ carrier gas has an etching function, while N₂ gas does not.

Therefore, when growing AlN thin films using N₂ alone or N₂-rich atmosphere, the AlN island particle diameter tends to be large and uneven, resulting in a rough surface.

At this time, air voids can be formed inside the AlN film by controlling the vertical growth (3D growth mode) speed and the horizontal growth (2D growth mode) speed.

The growth speed is controlled by controlling the growth pressure, V (N source)/III (Al source) ratio, and growth temperature.

Meanwhile, the AlN stress control region having a large amount of air voids can be formed in another way.

First, the AlN nucleation region (120) or a part of the AlN stress control region is grown on the AlN nucleation region (120).

Afterwards, Then, the AlN surface patterning is formed on the AlN nucleation region (120) or a part of the AlN stress control region through lithography and etching, and the AlN stress control region is completed through re-growth on the AlN surface patterning in MOCVD.

Here, nanometer-scale patterning and a relatively lower horizontal growth rate than the vertical growth rate are desirable for air void formation on the patterning.

Meanwhile, an AlN stress control region having a large amount of air voids can also be formed by growing AlGaN or AllnN on an AlN nucleation region (120) at a predetermined growth temperature (Tg) and decomposing and evaporating Ga or In at a high temperature higher than Tg and in a H₂ reducing atmosphere.

AlGaN grown at Tg is an alloy state of AlN and GaN with different growth temperatures, and when maintained at a temperature higher than Tg and in H₂ alone or H₂ reduction atmosphere for a certain period of time, AlGaN decomposes and GaN, which is a relatively low-temperature forming material, evaporates. As a result, porous AlN or AlGaN containing a large amount of air voids is formed.

AllnN also has the same mechanism, but decomposes and evaporates at a relatively lower temperature than AlGaN.

In addition, the AlN stress control region having a large amount of air voids can be formed with a predetermined thickness using a 2-dimensional growth mode in which AlN is preferentially grown in the horizontal direction through a pulsed NH₃ source supply, and a 3-dimensional growth mode in which AlN is preferentially grown in the vertical direction through a continuous NH₃ source supply.

By combining the mechanisms of injecting an ammonia (NH₃) source together with an aluminum source (TMAl) into a MOCVD reaction chamber to grow AlN in a 3D growth mode and continuously injecting the aluminum source while interrupting the injection of the ammonia source at predetermined time intervals to form AlN in a 2D growth mode, an AlN thick film including air voids can be formed. In particular, it is preferable to have a longer 2D growth mode process time than a 3D growth mode process time.

Meanwhile, the AlN stress control region having a large amount of Al vacancies can be formed by controlling the V (N source)/III (Al source) ratio below a predetermined growth pressure in MOCVD to generate a large amount of Al vacancies, while supplying a Ga or In source using the concept of isoelectric co-doping during AlN growth.

During the process of forming AlN in 3D growth mode, if the V (N source)/III (Al source) ratio is adjusted high, it is possible to grow an AlN film containing a large amount of aluminum vacancies.

The AlN buffer region (140) does not include air voids or Al vacancies, and has resolved the quality and reliability degradation phenomenon that occurs in the process of doping carbon (C) or iron (Fe) ions to grow conventional high-resistivity GaN materials.

The growth of the AlN buffer region (140) can be formed in a 2D growth mode using a carrier gas, H₂ alone or a gas mixed with a small amount of N₂ (i.e., H₂-rich atmosphere), for moving an aluminum organic metal source (TMAl, TEAl) into the MOCVD chamber.

When AlN is grown in a H₂ alone or H₂ rich atmosphere, the etching function of H₂ suppresses the vertical growth rate while promoting the horizontal growth rate, thereby forming a high-quality film with no or minimal air voids and aluminum vacancies.

Here, the 2D growth mode functions to minimize the density of threading dislocations, crystal defects induced in the AlN nucleation region.

What is claimed is:

1. An AlN thick film-based GaN HEMT epitaxy wafer, comprising:
a growth substrate made of a semi-insulating material or a conductive material;
an AlN nucleation region grown on the growth substrate;
an AlN stress control region grown on the AlN nucleation region and having an air void or an Al vacancy;
an AlN buffer region grown on the AlN stress control region and not including the air void and the Al vacancy; and
an active region grown on the AlN buffer region and including a GaN channel region and an AlGaN barrier region.

2. The AlN thick film-based GaN HEMT epitaxy wafer of claim 1, wherein the growth substrate is made of Si having the (111) plane as a growth plane or 4H-SiC having the Si-polar face as a growth plane.

3. The AlN thick film-based GaN HEMT epitaxy wafer of claim 1, wherein the AlN stress control region is formed to be relatively thicker than the AlN buffer region, and the AlN stress control region is provided with a large amount of micro-level-sized air voids or nano-level-sized Al vacancies.

4. The AlN thick film-based GaN HEMT epitaxy wafer of claim 1, further comprises a back barrier region made of Al(1-z)Ga(z)N (0<z<1), which is grown prior to the growth of the active region on the AlN buffer region.

5. An method for manufacturing the AlN thick film-based GaN HEMT epitaxy wafer of claim 1, comprising:
a step of forming the AlN stress control region having a large amount of air voids on the AlN nucleation region, and
wherein the step of forming the AlN stress control region is performed using a carrier gas that moves an aluminum organic metal source (TMAl, TEAl) into a MOCVD chamber, which is N₂ alone or a gas mixed with a small amount of H₂.

6. The method for manufacturing the AlN thick film-based GaN HEMT epitaxy wafer of claim 5, wherein the step of forming the AlN stress control region comprises a step of forming an AlN surface patterning through lithography and etching after growing the AlN nucleation region by a MOCVD process or after growing a portion of the AlN stress control region to a predetermined thickness; and a step of completing the AlN stress control region through regrowth on the AlN surface patterning in MOCVD.

7. The method for manufacturing the AlN thick film-based GaN HEMT epitaxy wafer of claim 5, wherein the step of forming the AlN stress control region comprises a step of growing AlGaN or AllnN material at a predetermined temperature (Tg) as a subsequent process after growing the AlN nucleation region, and a step of decomposing and evaporating Ga or In at a high temperature higher than Tg and in a H₂ reduction atmosphere.

8. The method for manufacturing the AlN thick film-based GaN HEMT epitaxy wafer of claim 5, wherein the step of forming the AlN stress control region is performed by forming a predetermined thickness by using a 2-dimensional growth mode in which AlN is preferentially grown in the horizontal direction through a pulsed NHs source supply, and a 3-dimensional growth mode in which AlN is preferentially grown in the vertical direction through a continuous NH₃ source supply.

9. The method for manufacturing the AlN thick film-based GaN HEMT epitaxy wafer of claim 1, comprising:
a step of forming the AlN stress control region having a large amount of Al vacancies on the AlN nucleation region, and
wherein the step of forming the AlN stress control region with a large amount of Al vacancies is performed by controlling the V (N source)/III (Al source) ratio below a predetermined growth pressure in MOCVD and supplying a Ga source and an In source for isoelectric co-doping during AlN growth.

10. The method for manufacturing the AlN thick film-based GaN HEMT epitaxy wafer of claim 5, further comprises a step of forming the AlN buffer region on the AlN stress control region, and
wherein the step of forming the AlN buffer region is formed in a 2D growth mode and by using H₂ alone or H₂-rich atmosphere as a carrier gas for moving an aluminum organic metal source (TMAl, TEAl) into the MOCVD chamber.
